(19) United States
(12) Patent Application Publication
(10) Pub. No.: US 2012/0250235 A1
(43) Pub. Date: Oct. 4, 2012

(54) INTERFACE MODULE WITH PROTECTION CIRCUIT AND ELECTRONIC DEVICE

(75) Inventors: REN-WEN HUANG, Shenzhen City (CN); TSUNG-JEN CHUANG, Tu-Cheng (TW); SHIH-FANG WONG, Tu-Cheng (TW)

(73) Assignees: HON HAI PRECISION INDUSTRY CO., LTD., Tu-Cheng (TW); Fu Tai Hua Industry (Shenzhen) Co., Ltd., ShenZhen City (CN)

(21) Appl. No.: 13/402,884

(22) Filed: Feb. 23, 2012

(30) Foreign Application Priority Data
Mar. 31, 2011 (CN) 201110080449.X

(51) Int. Cl. H05K 7/00

(52) U.S. Cl. 361/679.01

(57) ABSTRACT

An interface module includes an interface and a protection circuit. The interface includes a first input terminal for receiving a reference voltage representing ground (ground voltage), a second input terminal for receiving a power voltage, and a first output terminal for providing the ground voltage to a main circuit. The protection circuit includes a detection terminal for detecting the ground voltage of the first input terminal, a power input terminal for receiving the power voltage form the second input terminal, and a power output terminal for providing the power voltage to the main circuit.

### BACKGROUND

1. Technical Field

The present disclosure relates to an interface module with a protection circuit and an electronic device using the same.

2. Description of Related Art

Communication interfaces are found between different types of electronic devices and such interfaces may be connected via cables.

When an inactive electronic device is connected to an active electronic device via a cable (also called “hot plugging”) by a user, a power voltage from the active electronic device may be provided to the inactive electronic device without a ground voltage from the active electronic device being supplied first, and in these circumstances, the inactive electronic device may be damaged by the power voltage.

What is needed, therefore, is a means which can overcome the described limitations.

### BRIEF DESCRIPTION OF THE DRAWINGS

The components in the drawings are not necessarily drawn to scale, the emphasis instead being placed upon clearly illustrating the principles of the at least one embodiment. In the drawings, like reference numerals designate corresponding parts throughout the various views.

FIG. 1 shows a block diagram of an electronic device according to an embodiment of the present disclosure, the electronic device connected to an external electronic device having a first interface and including an interface module having a second interface and a protection circuit.

FIG. 2 shows a block diagram of the electronic device of FIG. 1 connected to the external electronic device via a cable.

FIG. 3 shows a block diagram of the protection circuit of FIG. 1.

FIG. 4 shows a schematic diagram of an embodiment of the interface module of FIG. 1.

FIG. 5 shows a schematic diagram of the first interface of the external electronic device of FIG. 1.

### DETAILED DESCRIPTION

Reference will be made to the drawings to describe specific exemplary embodiments of the present disclosure.

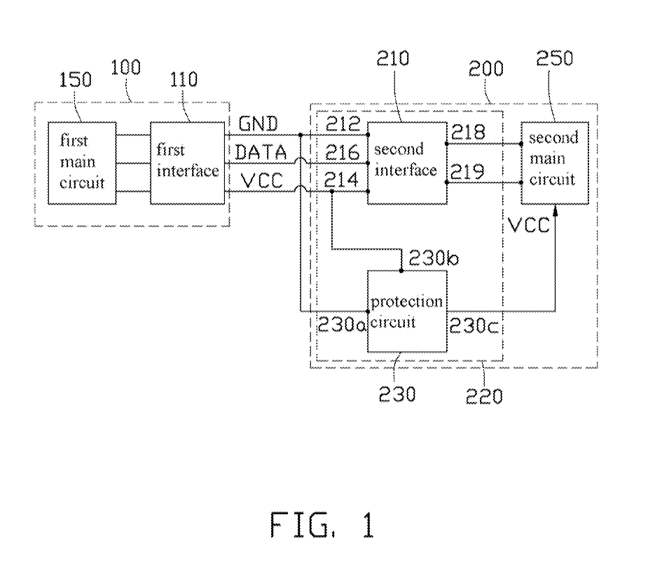

FIG. 1 shows a block diagram of an electronic device 200 according to an embodiment of the present disclosure. The electronic device 200 is connected to an external electronic device 100 for communication. The external electronic device 100 includes a first main circuit 150 and a first interface 110. The electronic device 200 includes an interface module 220 and a second main circuit 250.

The first main circuit 150 is configured for providing a ground voltage GND, a data voltage DATA, and a power voltage VCC to the electronic device 200 via the first interface 110. The interface module 220 is configured for receiving the ground voltage GND, the data voltage DATA, and the power voltage VCC from the first interface 110, and providing the ground voltage GND, the data voltage DATA, and the power voltage VCC to the second main circuit 250.

The interface module 220 includes a second interface 210 and a protection circuit 230. The second interface 210 includes a first input terminal 212 configured for receiving the ground voltage GND, a second input terminal 214 for receiving the power voltage VCC, a third input terminal 216 for receiving the data voltage DATA, a first output terminal 218 for providing the ground voltage GND to the second main circuit 250, a second output terminal 219 for providing the data voltage DATA to the second main circuit 250. The protection circuit 230 includes a detection terminal 230a, a power input terminal 230b, and a power output terminal 203c. The detection terminal 230a is connected to the first input terminal 212 for detecting the ground voltage GND. The power input terminal 230b is connected to the second input terminal 214 for receiving the power voltage VCC. The power output terminal 230c is connected to the second main circuit 250 for providing the power voltage VCC to the second main circuit 250. When the ground voltage GND is provided to the first input terminal 212, the power output terminal 230c outputs the power voltage VCC to the second main circuit 250. In an alternative embodiment, the detection terminal 230a can be connected to the first output terminal 218 for detecting the ground voltage GND.

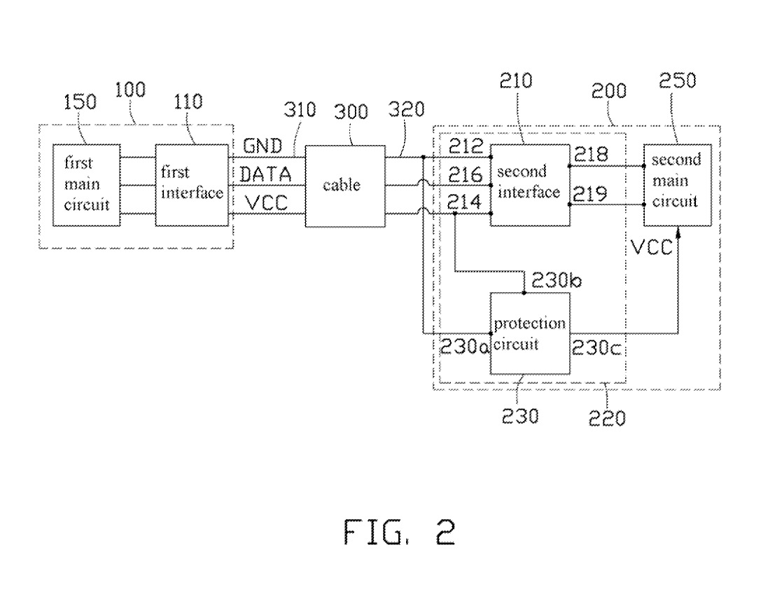

Referring to FIG. 2, in one embodiment, the device 200 may be connected to an external electronic device 100 via a cable 300. In detail, the cable 300 may include a plurality of input terminals 310 and a plurality of output terminals 320. The input terminals 310 are connected to the first interface 110 for receiving the ground voltage GND, the data voltage DATA, and the power voltage VCC. The output terminals 320 are connected to the second interface 210 for providing the ground voltage GND, the data voltage DATA, and the power voltage GND to the interface module 220.

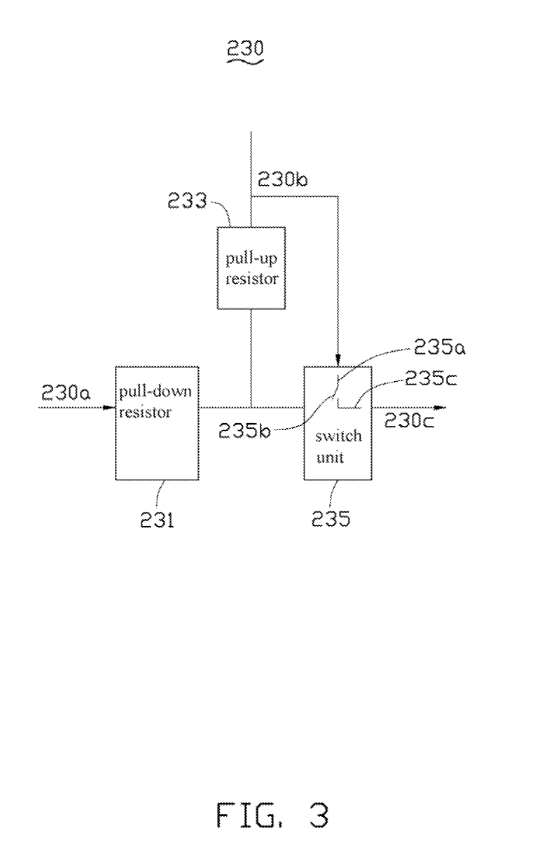

Referring to FIG. 3, a block diagram of the protection circuit 230 of FIG. 1 is shown. The protection circuit 230 includes a pull-up resistor 233, a pull-down resistor 231, and a switch unit 235. The switch unit 235 includes a control terminal 235b, a first connection terminal 235a, and a second connection terminal 235c. The control terminal 235b is connected to the detection terminal 230a via the pull-down resistor 231 for receiving and detecting the ground voltage GND, and the control terminal 235b is also connected to the power input terminal 230b via the pull-up resistor 233 for receiving the power voltage VCC. The first connection terminal 235a is connected to the power input terminal 230b for receiving the power voltage VCC. The second connection terminal 235c is connected to the power output terminal 230c.

When the ground voltage GND is provided to the control terminal 235b, the switch unit 235 is switched on by the ground voltage GND, and the power voltage VCC of the power input terminal 230b is provided to the power output terminal 230c via the first connection terminal 235a and the second connection terminal 235c, such that the power voltage VCC can be provided to the second main circuit 250 by the power output terminal 230c.

In one embodiment, the switch unit 235 is a p-channel metal oxide semiconductor (PMOS) transistor. A gate electrode, a source electrode, and a drain electrode of the PMOS transistor respectively serve as the control terminal 235b, the first connection terminal 235a, and the second connection terminal 235c.

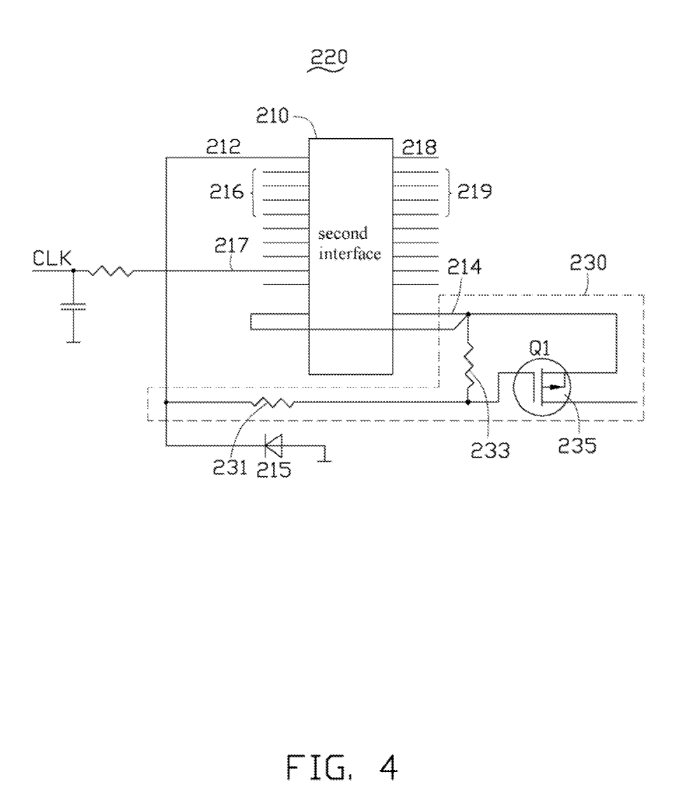

Referring to FIG. 4, a schematic diagram of an embodiment of the interface module 220 of FIG. 1 is shown. The second interface 210 may further include a plurality of third input terminals 216 for receiving data voltages, a plurality of second output terminals 219 for outputting the data voltages to the second main circuit 250, a clock signal input terminal 217 for receiving a clock signal CLK, and a diode 215. An anode of the diode 215 is grounded, and a cathode of the diode 215 is connected to the first input terminal 212 for receiving and detecting the ground voltage GND. The second interface 210 may be a connector including a housing and a plurality of wires. The wires are fixed within the shell, and ends of each wire serve as an input terminal and an output terminal, such as the first input terminal 212 and the first output terminal 218, or the third input terminal 216 and the second output terminal 219.

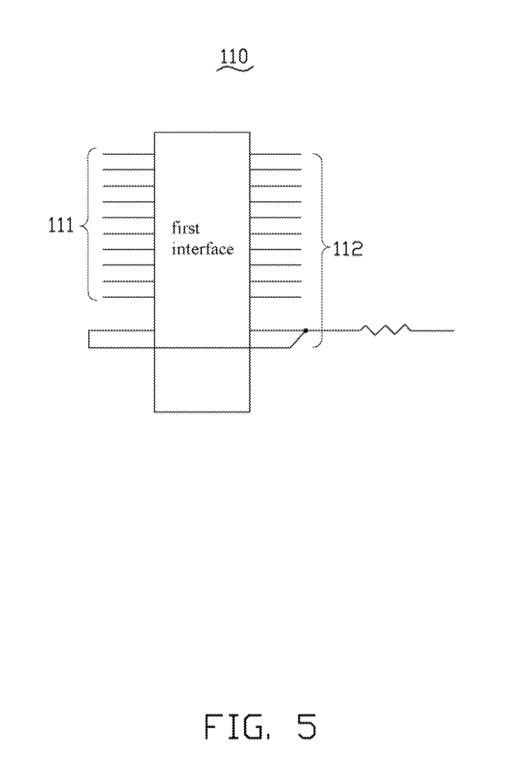

Referring to FIG. 5, a schematic diagram of an embodiment of the first interface of the external electronic device of FIG. 1 is shown. The first interface 110 may include a plurality of input terminals 111 and a plurality of output terminals 112. The input terminals 111 are configured to connect to the first main circuit 150 for receiving the ground voltage GND, the data voltage DATA, the clock signal CLK, and the power voltage VCC, and the output terminals 112 are configured to forward the ground voltage GND, the data voltage DATA, the clock signal CLK, and the power voltage VCC to the interface module 220.

When the electronic device 200, which serves as an inactive electronic device, is connected to an active electronic device such as the external electronic device 100, if the power voltage VCC from the device 100 has been provided to the second input terminal 214 but the ground voltage GND has not been provided to the first input terminal 212, the detection terminal 230a electrically floats, and the power input terminal 230b receives the power voltage VCC. Due to the power voltage through the pull-up resistor 233, the control terminal 235b is at a high voltage level (logic 1), the switch unit 235 is switched off, the power voltage VCC can not be provided to the power output terminal 230c, and the second main circuit 250 cannot receive the power voltage VCC from the interface module 220.

When the power voltage VCC from the device 100 is present on the second input terminal 214 and the ground voltage GND is present on the first input terminal 212, the detection terminal 230a receives the ground voltage GND, and the power input terminal 230b receives the power voltage VCC. The first output terminal 218 directly provides the ground voltage GND (from the first input terminal) to the second main circuit 150. The ground voltage GND at the pull-down resistor 231 pulls the control terminal 235b down to a low voltage level (logic 0) and the switch unit 235 is thus switched on, and the power voltage VCC is provided to the power output terminal 230c via the two connection terminals 235a and 235c. Then the second main circuit 250 receives the ground voltage GND from the first input terminal 218 and the power voltage VCC from the power output terminal 230c and is activated.

Due to the protection circuit 230, the power voltage VCC is not provided to the second main circuit 250 until the first input terminal 212 receives the ground voltage GND, while the first output terminal 218 directly provides the ground voltage GND from the first input terminal 212 to the second main circuit 250. That is, even if the power voltage VCC is provided to the second interface 210 before the ground voltage GND is detected, the second main circuit 250 cannot receive the power voltage VCC before the ground voltage GND, and accordingly, the second main circuit 250 is protected from damage by the power voltage VCC.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. An interface module, comprising:
an interface comprising a first input terminal configured for receiving a ground voltage, a second input terminal configured for receiving a power voltage, and a first output terminal configured for providing the ground voltage to a main circuit, and
a protection circuit comprising a detection terminal configured for detecting the ground voltage of the first input terminal, a power input terminal configured for receiving the power voltage from the second input terminal, and a power output terminal configured for providing the power voltage to the main circuit,
wherein in the condition of the detection terminal receives the ground voltage from the first input terminal, the power output terminal provides the power voltage to the main circuit.

2. The interface module of claim 1, wherein the protection circuit comprises a switch unit connected between the power input terminal and the power output terminal, if the detection terminal receives the ground voltage, the switch unit is switched on, otherwise if the detection terminal does not receive the ground voltage, the switch unit is switched off.

3. The interface module of claim 2, wherein the protection circuit comprises a pull-up resistor, the switch unit comprising a first connection terminal, a second connection terminal, and a control terminal, the first connection terminal connected to the power input terminal, the second connection terminal connected to the power output terminal, the control terminal connected to the power input terminal via the pull-up resistor for receiving the power voltage, and the control terminal also connected to the detection terminal for receiving the ground voltage.

4. The interface module of claim 3, wherein the protection circuit further comprises a pull-down resistor connected between the control terminal and the detection terminal.

5. The interface module of claim 3, wherein the switch unit is p-channel metal oxide semiconductor (PMOS) transistor, and a gate electrode, a source electrode, and a drain electrode of the PMOS transistor are served as the control terminal, the first connection terminal, and the second connection terminal, respectively.

6. The interface module of claim 1, wherein the interface further comprises a third input terminal configured for receiving a data voltage and a second output terminal configured for providing the data voltage to the main circuit.

7. An electronic device, comprising:
a main circuit;
an interface comprising a first input terminal configured for receiving a ground voltage, a second input terminal configured for receiving a power voltage, and a first output terminal configured for providing the ground voltage to the main circuit, and
a protection circuit comprising a detection terminal configured for detecting the ground voltage of the first input terminal, a power input terminal configured for receiving the power voltage from the second input terminal, and a power output terminal configured for providing the power voltage to the main circuit,
wherein in the condition of the detection terminal receives the ground voltage from the first input terminal, the power output terminal provides the power voltage to the main circuit.

8. The electronic device of claim 7, wherein the protection circuit comprises a switch unit connected between the power input terminal and the power output terminal, if the detection terminal receives the ground voltage, the switch unit is switched on, otherwise if the detection terminal does not receive the ground terminal, the switch unit is switched off.

9. The electronic device of claim 8, wherein the protection circuit comprises a pull-up resistor, the switch unit comprising a first connection terminal, a second connection terminal, and a control terminal, the first connection terminal connected to the power input terminal, the second connection terminal connected to the power output terminal, the control terminal connected to the power input terminal via the pull-up resistor for receiving the power voltage, and the control terminal also connected to the detection terminal for receiving the ground voltage.

10. The electronic device of claim 9, wherein the protection circuit further comprises a pull-down resistor connected between the control terminal and the detection terminal.

11. The electronic device of claim 9, wherein the switch unit is p-channel metal oxide semiconductor (PMOS) transistor, and a gate electrode, a source electrode, and a drain electrode of the PMOS transistor are served as the control terminal, the first connection terminal, and the second connection terminal, respectively.

12. The electronic device of claim 7, wherein the interface further comprises a third input terminal configured for receiving a data voltage and a second output terminal configured for providing the data voltage to the main circuit.

13. An electronic device, comprising:
a main circuit, and
an interface module comprising an interface configured for receiving a power voltage and a ground voltage and a protection circuit,
wherein the protection circuit detects whether the ground voltage is provided to the interface, if the ground voltage is provided to the interface, the protection circuit provides the power voltage to the main circuit.

14. The electronic device of claim 13, wherein the protection circuit comprises a pull-up resistor and a switch unit, and the switch unit comprises a first connection terminal, a second connection terminal, and a control terminal, the first connection terminal connected to the interface for receiving the power voltage, the second connection terminal connected to main circuit for providing the power voltage, the control terminal connected to the interface via the pull-up resistor for receiving the power voltage, and the control terminal also connected to the interface for receiving the ground voltage.

15. The electronic device of claim 14, wherein the protection circuit further comprises a pull-down resistor connected between the control terminal and the interface.

16. The electronic device of claim 14, wherein the switch unit is p-channel metal oxide semiconductor (PMOS) transistor, and a gate electrode, a source electrode, and a drain electrode of the PMOS transistor are served as the control terminal, the first connection terminal, and the second connection terminal, respectively.
